(19) United States
(12) Patent Application Publication
(10) Pub. No.: US 2022/0301862 A1
(43) Pub. Date: Sep. 22, 2022

(54) MONOALKOXYSILANES AND DENSE ORGANOSILICA FILMS MADE THEREFROM

(71) Applicant: VERSUM MATERIALS US, LLC, TEMPE, AZ (US)

(72) Inventors: MANCHAO XIAO, SAN DIEGO, CA (US); WILLIAM ROBERT ENTLEY, GILBERT, AZ (US); DANIEL P. SPENCE, CARLSBAD, CA (US); RAYMOND NICHOLAS VRTIS, CARLSBAD, CA (US); JENNIFER LYNN ANNE ACHTYL, CHANDLER, AZ (US); ROBERT GORDON RIDGEWAY, CHANDLER, AZ (US); XINJIAN LEI, VISTA, CA (US)

(73) Assignee: VERSUM MATERIALS US, LLC, TEMPE, AZ (US)

(21) Appl. No.: 17/642,185

(22) PCT Filed: Sep. 10, 2020
(86) PCT No.: PCT/US2020/050095

§ 371 Date: Mar. 10, 2022

Related U.S. Application Data
(60) Provisional application No. 62/899,824, filed on Sep. 13, 2019.

(51) Int. Cl. H01L 21/02; C23C 16/40; C23C 16/513

(52) U.S. Cl. CPC H01L 21/02216; C23C 16/401; C23C 16/513; H01L 21/02274; H01L 21/02131

(57) ABSTRACT

A method for making a dense organosilicon film with improved mechanical properties, the method comprising the steps of: providing a substrate within a reaction chamber; introducing into the reaction chamber a gaseous composition comprising a novel monoalkoxysilane; and applying energy to the gaseous composition comprising a novel monoalkoxysilane in the reaction chamber to induce reaction of the gaseous composition comprising a novel monoalkoxysilane to deposit an organosilicon film on the substrate, wherein the organosilicon film has a dielectric constant of from about 2.80 to about 3.30, an elastic modulus of from about 9 to about 32 GPa, and an at. % carbon of from about 10 to about 30 as measured by XPS.

### CROSS-REFERENCE TO RELATED APPLICATIONS

This application is a 371 National entry of International Application No. PCT/US2020/050095 filed on Sep. 10, 2020, which claims the benefit of U.S. Provisional Application No. 62/899,824 filed on Sep. 13, 2019. The disclosures of those applications are hereby incorporated by reference in their entirety.

### BACKGROUND OF THE INVENTION

Described herein is a composition and method for formation of a dense organosilica dielectric film using monoalkoxysilane as a precursor to the film. More specifically, described herein is a composition and chemical vapor deposition (CVD) method for forming a dense film having a dielectric constant, k≥2.7, wherein the film has a high elastic modulus and excellent resistance to plasma induced damage as compared to films made from conventional precursors.

The electronics industry utilizes dielectric materials as insulating layers between circuits and components of integrated circuits (IC) and associated electronic devices. Line dimensions are being reduced in order to increase the speed and memory storage capability of microelectronic devices (e.g., computer chips). As the line dimensions decrease, the insulating requirements for the interlayer dielectric (ILD) become much more rigorous. Shrinking the spacing requires a lower dielectric constant to minimize the RC time constant, where R is the resistance of the conductive line and C is the capacitance of the insulating dielectric interlayer. Capacitance (C) is inversely proportional to spacing and proportional to the dielectric constant (k) of the interlayer dielectric (ILD). Conventional silica (SiO₂) CVD dielectric films produced from SiH₄ or TEOS (Si(OCH₂CH₃)₄, tetraethylorthosilicate) and O₂ have a dielectric constant k greater than 4.0. There are several ways in which industry has attempted to produce silica-based CVD films with lower dielectric constants, the most successful being the doping of the insulating silicon oxide film with organic groups providing dielectric constants ranging from about 2.7 to about 3.5. This organosilica glass is typically deposited as a dense film (density about 1.5 g/cm³) from an organosilicon precursor, such as a methylsilane or siloxane, and an oxidant, such as O₂ or N₂O. Organosilica glass will be herein be referred to as OSG.

Patents, published applications, and publications in the field of porous ILD by CVD methods field include: EP 1 119 035 A2 and U.S. Pat. No. 6,171,945, which describe a process of depositing an OSG film from organosilicon precursors with labile groups in the presence of an oxidant such as N₂O and optionally a peroxide, with subsequent removal of the labile group with a thermal anneal to provide porous OSG; U.S. Pat. Nos. 6,054,206 and 6,238,751, which teach the removal of essentially all organic groups from deposited OSG with an oxidizing anneal to obtain porous inorganic SiO₂; EP 1 037 275, which describes the deposition of an hydrogenated silicon carbide film which is transformed into porous inorganic SiO₂ by a subsequent treatment with an oxidizing plasma; and U.S. Pat. No. 6,312,793 B1, WO 00/24050, and a literature article Grill, A. Patel, V. Appl. Phys. Lett. (2001), 79(6), pp. 803-805, which all teach the co-deposition of a film from an organosilicon precursor and an organic compound, and subsequent thermal anneal to provide a multiphase OSG/organic film in which a portion of the polymerized organic component is retained. In the latter references, the ultimate final composition of the films indicate residual porogen and a high hydrocarbon film content of approximately 80 to 90 atomic %. Further, the final films retain the SiO₂-like network, with substitution of a portion of oxygen atoms for organic groups.

US Patent appl No. US201110113184A discloses a class of materials that can be used to deposit insulating films with dielectric constants ranging from about k=2.4 to k=2.8 via a PECVD process. The materials comprise Si compounds that have 2 hydrocarbon groups that can be bound to each other to form a cyclic structure in cooperation with a Si atom or having ≥1 branched hydrocarbon group. In the branched hydrocarbon group, an α-C which is a C atom bound to a Si atom constitutes a methylene group, and a β-C which is a C atom bound to the methylene group or a γ-C which is a C atom bound to the β-C is the branching point. Specifically two of the alkyl groups bonded to the Si include CH₂CH(CH₃)CH₃, CH₂CH(CH₃)CH₂CH₃, CH₂CH₂CH(CH₃)CH₃, CH₂C(CH₃)₂CH₃ and CH₂CH₂CH(CH₃)₂CH₃, and a third group bonded to the silicon includes OCH₃ and OC₂H₅. There are several disadvantages to this approach. First is the requirement for large alkyl groups that include a branched alkyl group in the precursor structure. Such molecules are expensive to synthesize and, because of their inherently high molecular weight, typically have high boiling points and low volatility. A high boiling point and low volatility make it challenging to effectively deliver such molecules in the vapor phase, as required for PECVD processes. Further, the high density of SiCH₂Si groups in the low k films disclosed in this approach are formed after the as deposited films are exposed to ultraviolet radiation (i.e, after the films are UV cured). However, the formation of SiCH₂Si groups upon exposure to ultraviolet irradiation has been well documented in the literature and thus cannot be attributed to the deposition process alone, for example as disclosed in Grill, A., “PECVD low and Ultralow Dielectric Constant Materials: From Invention and Research to Products” J. Vac. Sci. Technol. B, 2016, 34, 020801-1-020801-4. Finally the values reported of the dielectric constant in this approach are low, less than or equal to 2.8. Thus, this approach is more akin to a tethered porogen approach for generating porous low k films than it is for the deposition of dense low k films in the absence of post deposition processing (i.e., UV curing).

Plasma or process induced damage (PID) in low k films is caused by the removal of carbon from the film during plasma exposure, particularly during etch and photoresist strip processes. This changes the plasma damaged region from hydrophobic to hydrophilic. Exposure of the hydrophilic SiO₂ like damaged layer to dilute HF-based wet chemical post plasma treatments (with or without additives such as surfactants) results in an increase in the effective dielectric constant of the low k film and a rapid dissolution of the plasma damaged layer. In patterned low k wafers, this results in profile erosion. Process induced damage and the resulting profile erosion in low k films is a significant problem that device manufacturers must overcome when integrating low k materials in a ULSI interconnect.

Films with increased mechanical properties (higher elastic modulus, higher hardness) reduce line edge roughness in patterned features, reduce pattern collapse, and provide greater internal mechanical stress within an interconnect, reducing failures due to electromigration. Thus, there is a need for dense low k films with excellent resistance to PID and the highest possible mechanical properties at a given dielectric constant, preferably without the requirement for post deposition treatments such as UV curing. UV curing not only decreases throughput, increases cost, and increases complexity, but it also reduces carbon content and introduces porosity into the film. Reduced carbon content and increased porosity will result in greater plasma induced damage. The precursors in this invention are designed to deposit dense low k films with dielectric constants between about 2.8 and 3.3, with mechanical strength that exceeds that of prior art precursors, with good resistance to plasma induced damage, without the need for post deposition treatments.

### BRIEF SUMMARY OF THE INVENTION

The method and composition described herein fulfill one or more needs described above. The monoalkoxysilane precursor can be used to deposit dense low k films with k valves between about 2.8 to about 3.3 without the need for post deposition treatments, such films exhibiting an unexpectedly high elastic modulus/hardness, and an unexpectedly high resistance to plasma induced damage.

In one aspect, the disclosure provides a method for making a dense organosilica film with improved mechanical properties, the method comprising the steps of: providing a substrate within a reaction chamber; introducing into the reaction chamber a gaseous composition comprising monoalkoxysilane having the structure of given in Formulae (1) or (2):

R¹R²MeSiOR³ (1)

where R¹ and R² are selected independently from a linear or branched C₁ to C₅ alkyl, preferably methyl, ethyl, propyl, iso-propyl, butyl, sec-butyl, or tert-butyl and R³ is selected from a linear or branched C₁ to C₅ alkyl, preferably methyl, ethyl, propyl, iso-propyl, butyl, sec-butyl, iso-butyl, or tert-butyl, more preferably iso-propyl, sec-butyl, iso-butyl, and tert-butyl;

R⁴(Me)₂SiOR⁵ (2)

where R⁴ is selected from a linear or branched C₁ to C₅ alkyl, preferably methyl, ethyl, n-propyl, iso-propyl, n-butyl, sec-butyl, or tert-butyl and R⁵ is selected from a linear or branched C₁ to C₅ alkyl, preferably methyl, ethyl, propyl (i.e. n-Pr or Pr-n), iso-propyl (i.e i-Pr or Pr-i or iso-Pr or Pr-iso or Prⁱ), butyl (i.e n-Bu or Bu-n or Buⁿ), sec-butyl (i.e sec-Bu or Bu-sec or s-Bu or Bu-s or Bu^{s}), iso-butyl (i.e. iso-Bu or Bu-iso i-Bu or Bu-i or Buⁱ), or tert-butyl (tert-Bu or Bu-tert or t-Bu or Bu-t or Bu^{t}), more preferably iso-propyl, sec-butyl, iso-butyl, and tert-butyl.

For the above Formulae combinations of alkyl groups are selected such that the molecules boiling point is less than 200° C. In addition for optimum performance R groups are chosen that form secondary or tertiary radicals upon homolytic bond dissociation (e.g., SiO—R→SiO.+R., where R. is a secondary or tertiary radical such as an isopropyl radical, sec-butyl radical or a tert-butyl radical); and applying energy to the gaseous composition comprising monoalkoxysilane in the reaction chamber to induce reaction of the gaseous composition comprising monoalkoxysilane to deposit an organosilicon film on the substrate, wherein the organosilica film has a dielectric constant of from about 2.8 to about 3.3 and an elastic modulus of from about 9 to about 32 GPa.

In another aspect, the disclosure provides a method for making a dense organosilica film with improved mechanical properties, the method comprising the steps of: providing a substrate within a reaction chamber; introducing into the reaction chamber a gaseous composition comprising monoalkoxysilane; and applying energy to the gaseous composition comprising monoalkoxysilane in the reaction chamber to induce reaction of the gaseous composition comprising monoalkoxysilane to deposit an organosilica film on the substrate, wherein the organosilica film has a dielectric constant of from about 2.8 to about 3.3, an elastic modulus of from about 9 to about 32 GPa, and an at. % carbon of from about 10 to about 30 as measured by XPS.

### BRIEF DESCRIPTION OF THE DRAWINGS

FIG. 1 is a graph depicting a relationship between the % Si-Me groups in a thin film versus mechanical strength;

FIG. 2 is a chart depicting GC-MS data for iso-propyldimethyl-iso-propoxysilane as synthesized according to the methodology described in Example 1;

FIG. 3 is a graph depicting infrared spectra of the dense low k films formed from the three precursors di(ethyl)methyl-isopropoxysilane (DEMIPS), diethoxy-methylsilane (DEMS®) and 1-methyl-1-isopropoxy-1-silacyclopentane (MPSCP); and

FIG. 4 is a plot of the dielectric constant against XPS carbon content for exemplary dense low k films deposited using di(ethyl)methyl-isopropoxysilane (DEMIPS) as the low k precursor relative to dense low k films deposited using diethoxy-methylsilane (DEMS®) and 1-methyl-1-isopropoxy-1-silacyclopentane (MPSCP) as the low k precursor.

### DETAILED DESCRIPTION OF THE INVENTION

Described herein is a chemical vapor deposition method for making a dense organosilica film with improved mechanical properties, the method comprising the steps of: providing a substrate within a reaction chamber; introducing into the reaction chamber a gaseous composition comprising a monoalkoxysilane, a gaseous oxidant such as O₂ or N₂O, and an inert gas such as He; and applying energy to the gaseous composition comprising monoalkoxysilane in the reaction chamber to induce reaction of the gaseous composition comprising monoalkoxysilane to deposit an organosilica film on the substrate, wherein the organosilica film has a dielectric constant of from about 2.8 to about 3.3, an elastic modulus of from about 9 to about 32 GPa, and an at. % carbon of from about 10 to about 30 as measured by XPS, preferably a dielectric constant of from about 2.9 to about 3.2, an elastic modulus of from about 10 to about 29 GPa, and an at. % carbon from about 10 to about 30 as measured by XPS.

Also described herein is a method for making a dense organosilica film with improved mechanical properties, the method comprising the steps of: providing a substrate within a reaction chamber; introducing into the reaction chamber a gaseous composition comprising monoalkoxysilane, a gaseous oxidant such as O₂ or N₂O, and an inert gas such as He; and applying energy to the gaseous composition comprising monoalkoxysilane to deposit an organosilica film on the substrate, wherein the organosilica film has a dielectric constant of from about 2.70 to about 3.3 and an elastic modulus of from about 9 to about 32 GPa.

The monoalkoxysilane provides unique attributes that make it possible to achieve a relatively low dielectric constant for a dense organosilica film and to surprisingly exhibit excellent mechanical properties compared to prior art structure former precursors such as diethoxymethylsilane (DEMS®) and 1-isopropoxy-1-methyl-1-silacyclopentane (MPSCP). Not bound by theory, it is believed monoalkoxysilanes in this invention can provide stable radicals such as CH₃CH₂., (CH₃)₂CH., (CH₃)₃C., during plasma enhanced chemical vapor deposition when R¹, and R² are selected from the group consisting of ethyl, propyl, iso-propyl, butyl, sec-butyl, or tert-butyl and R³ is selected from the group of methyl, ethyl, propyl, iso-propyl, butyl, sec-butyl, iso-butyl, or tert-butyl which would provide more stable radicals than methyl as disclosed in prior art such as Me₃SiOMe or Me₃SiOEt (Bayer, C., et al. “Overall Kinetics of SiOx Remote-PECVD using Different Organosilicon Monomers,” 116-119 Surf. Coat. Technol. 874 (1999)) The higher density of stable radicals such as CH₃CH₂—, (CH₃)₂CH., and (CH₃)₃C. in the plasma increase the probability of abstraction of a hydrogen atom from a terminal silicon methyl group (Si—CH₃) in the precursor (forming SiCH₂.) and facilitating the formation of disilylmethylene groups (i.e. Si—CH₂—Si moieties) in the as deposited film. Presumably in the case of R¹Me₂SiOR³ type molecules, the higher density of terminal silicon methyl groups in the precursor (two per silicon atom) further favors the formation of high densities of disilylmethylene groups (Si—CH₂—Si) in the as deposited film.

It is well known in organic chemistry that more energy must be supplied to generate a primary carbon radical (such as an ethyl radical, CH₃CH₂.) than a secondary carbon radical (such as an isopropyl radical (CH₃)₂CH.). This is due to the greater stability of the isopropyl radical relative to the ethyl radical. The same principle applies to the homolytic bond dissociation of the oxygen-carbon bond in silicon alkoxy groups; it requires less energy to dissociate the oxygen-carbon bond in an isopropxysilane than in an ethoxysilane. Similarly, it takes less energy to dissociate the silicon-carbon bond in an isopropylsilane than in an ethylsilane. It is assumed that bonds that require less energy to break are more readily dissociated in a plasma. Thus, monoalkoxysilanes having Si—OPrⁱ, or Si-OBu^{s} or Si-OBu^{t} groups could result in a higher density of SiO. type radicals relative to those having Si-OEt group in a plasma. Likewise monoalkoxysilanes having Si-Et, or Si—Prⁱ, Si-Bu^{s} or Si-Bu^{t} groups could result in a higher density of Si. type radicals relative to those having just Si-Me groups in a plasma. Presumably this contributes to the differentiated properties of deposited using monoalkoxysilanes having Si—OPrⁱ, or Si-OBu^{s} or Si-OBu^{t} groups relative to monoalkoxysilanes having Si-OEt.

Some of advantages over the prior art achieved with monoalkoxysilanes as silicon precursors include but not limited to:
Low Cost and Ease of Synthesis
High Elastic Modulus/High Hardness
High Wide Range of XPS Carbon
High Disilylmethylene Density

Table 1 lists select monoalkoxysilanes having Formulae 1 and 2. Although there are numerous compounds disclosed, the most preferred molecules are those with a combination of alkyl groups (R¹, R², R³, R⁴, and R⁵) selected such that the molecules' boiling point is less than 200° C. (preferably less than 150° C.). In addition for optimum performance R¹, R², R³, R⁴, and R⁵ groups may be chosen such that some or all form secondary or tertiary radicals upon homolytic bond dissociation (e.g., Si—R²→Si.+R². or SiO—R³→SiO.+R³., where R². and R³. are a secondary or tertiary radical such as the isopropyl radical, sec-butyl radical, tert-butyl radical, or cyclohexyl radical). A most preferred example being di-iso-propylmethyl(iso-propoxy)silane, with a predicted boiling point of 168° C. at 760 Torr.

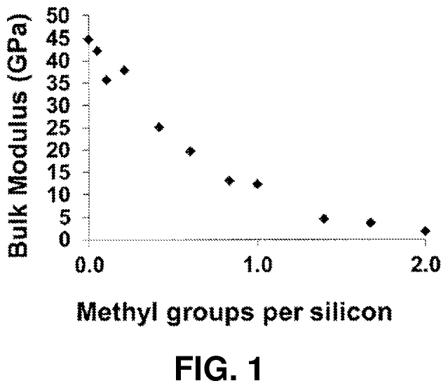

TABLE 1
List of exemplary
monoalkoxysilanes
having Formulae
1 and 2

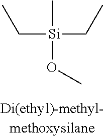

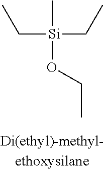

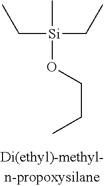

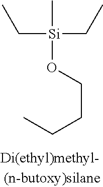

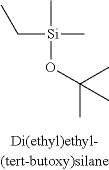

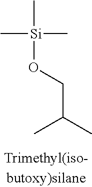

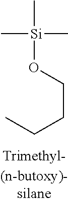

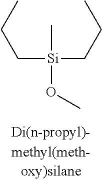

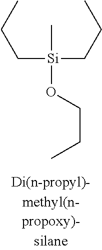

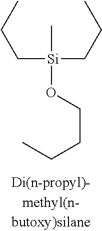

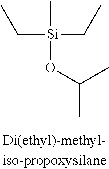

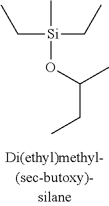

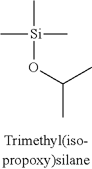

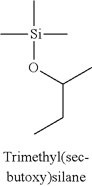

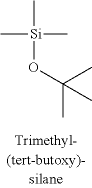

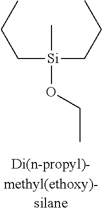

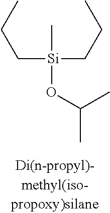

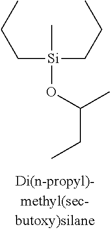

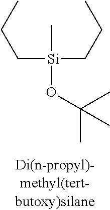

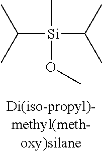

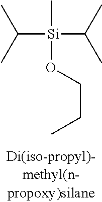

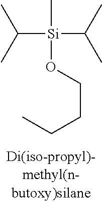

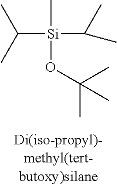

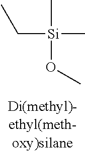

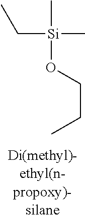

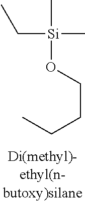

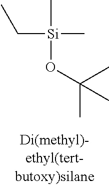

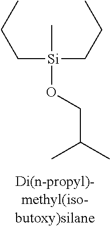

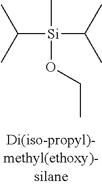

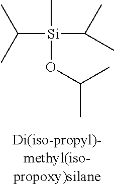

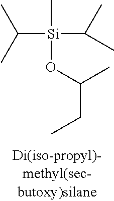

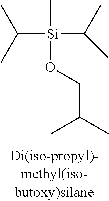

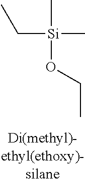

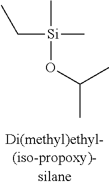

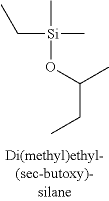

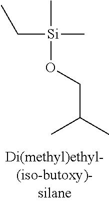

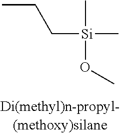

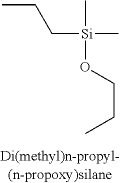

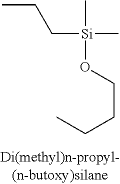

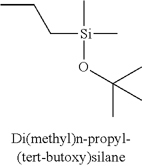

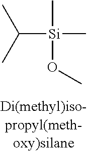

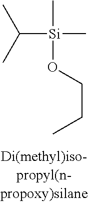

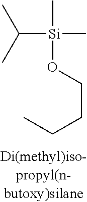

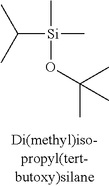

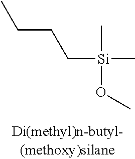

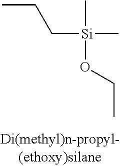

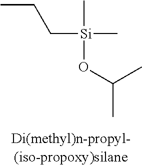

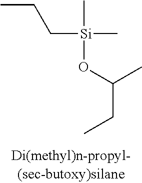

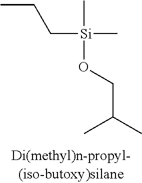

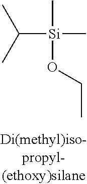

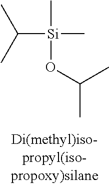

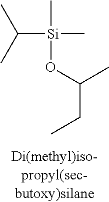

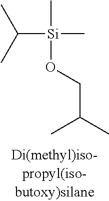

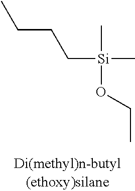

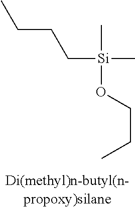

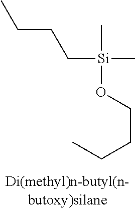

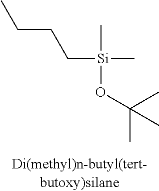

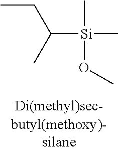

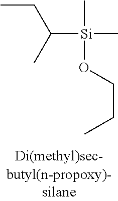

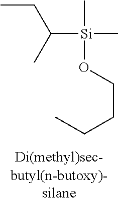

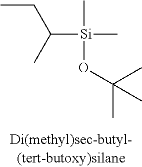

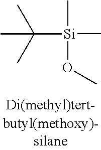

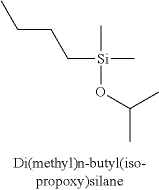

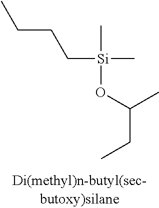

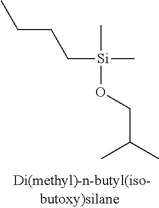

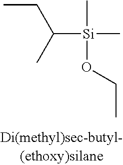

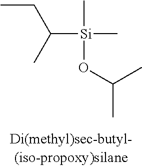

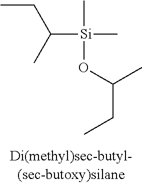

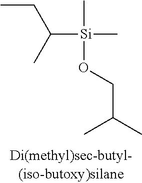

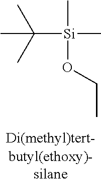

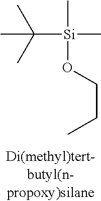

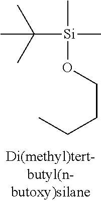

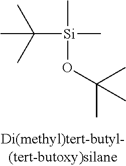

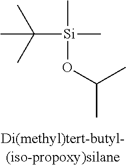

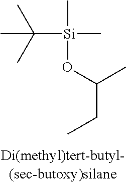

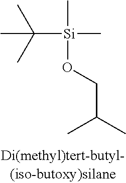

Whereas prior art silicon-containing structure-forming precursors, for example DEMS®, polymerized, once energized in the reaction chamber, to form a structure having an —O— linkage (e.g., —Si—O—Si— or Si—O—C—) in the polymer backbone, it is believed that monoalkoxysilane compounds having Formula (1) or Formula (2), such as, for example, the DEMIPS molecule polymerizes to form a structure where a high percentage of the —O— bridge in the backbone is replaced with a —CH₂— methylene or —CH₂CH₂— ethylene bridge(s). In films deposited using DEMS® as the structure forming precursor where the carbon exists mainly in the form of terminal Si-Me groups there is a relationship between the % Si-Me (directly related to % C) versus mechanical strength, see for example the modeling work shown in FIG. 1 where the replacement of a bridging Si—O—Si group with two terminal Si-Me groups decreases the mechanical properties because the network structure is disrupted. In the case of monoalkoxysilane compounds having Formula (1) or Formula (2) it is believed that the precursor structure is broken during film deposition to form SiCH₂Si or SiCH₂CH₂Si bridging groups. In this manner, one can incorporate carbon in the form of a bridging group so that, from a mechanical strength view, the network structure is not disrupted by increasing the carbon content in the film. Not being bound by theory, this attribute adds carbon to the film, that allows the film to be more resilient to carbon depletion of the dense film from processes such as etching of the film, plasma ashing of photoresist, and NH₃ plasma treatment of copper surfaces. Carbon depletion in dense low k films can cause increases in the effective dielectric constant of the film, problems with film etching and feature bowing during wet cleaning steps, and/or integration issues when depositing copper diffusion barriers. While prior art structure formers such as MPSCP can deposit low k films with exceptionally high densities of bridging SiCH₂Si and/or SiCH₂CH₂Si groups, these films also have a very high Si-Me density and total carbon content, that ultimately limits the highest elastic modulus achievable with this class of prior art low k precursors.

The monoalkoxysilanes having Formulae 1 and 2 according to the present invention and compositions comprising the monoalkoxysilanes compounds having Formulae 1 and 2 according to the present invention are preferably substantially free of halide ions. As used herein, the term “substantially free” as it relates to halide ions (or halides) such as, for example, chlorides (i.e. chloride-containing species such as HCl or silicon compounds having at least one Si—Cl bond) and fluorides, bromides, and iodides, means less than 5 ppm (by weight) measured by Ion chromatography (IC), preferably less than 3 ppm measured by IC, and more preferably less than 1 ppm measured by IC, and most preferably 0 ppm measured by IC. Chlorides are known to act as decomposition catalysts for the silicon precursor compounds. Significant levels of chloride in the final product can cause the silicon precursor compounds to degrade. The gradual degradation of the silicon precursor compounds may directly impact the film deposition process making it difficult for the semiconductor manufacturer to meet film specifications. In addition, the shelf-life or stability is negatively impacted by the higher degradation rate of the silicon precursor compounds thereby making it difficult to guarantee a 1-2 year shelf-life. Therefore, the accelerated decomposition of the silicon precursor compounds presents safety and performance concerns related to the formation of these flammable and/or pyrophoric gaseous byproducts. The monoalkoxysilanes having Formulae 1 and 2 are preferably substantially free of metal ions such as, Li⁺, Na⁺, K⁺, Mg²⁺, Ca²⁺, Al³⁺, Fe²⁺, Fe²⁺, Fe³⁺, Ni²⁺, Cr³⁺. As used herein, the term “substantially free” as it relates to Li, Na, K, Mg, Ca, Al, Fe, Ni, Cr means less than 5 ppm (by weight), preferably less than 3 ppm, and more preferably less than 1 ppm, and most preferably 0.1 ppm as measured by ICP-MS. In some embodiments, the silicon precursor compounds having Formula A are free of metal ions such as, Li⁺, Na⁺, K⁺, Mg²⁺, Ca²⁺, Al³⁺, Fe²⁺, Fe²⁺, Fe³⁺, Ni²⁺, Cr³⁺. As used herein, the term “free of” metal impurities as it relates to Li, Na, K, Mg, Ca, Al, Fe, Ni, Cr, means less than 1 ppm, preferably 0.1 ppm (by weight) as measured by ICP-MS, most preferably 0.05 ppm (by weight) as measured by ICP-MS or other analytical method for measuring metals. In addition, the monoalkoxysilanes having Formulae 1 and 2 preferably have purity of 98 wt. % or higher, more preferably 99 wt. % or higher as measured by GC when used as precursor to deposit the silicon-containing films.

The low k dielectric films are organosilica glass (“OSG”) films or materials. Organosilicates are employed in the electronics industry, for example, as low k materials. Material properties depend upon the chemical composition and structure of the film. Since the type of organosilicon precursor has a strong effect upon the film structure and composition, it is beneficial to use precursors that provide the required film properties to ensure that the addition of the needed amount of porosity to reach the desired dielectric constant does not produce films that are mechanically unsound. The method and composition described herein provides the means to generate low k dielectric films that have a desirable balance of electrical and mechanical properties as well as other beneficial film properties as high carbon content to provide improved integration plasma resistance.

In certain embodiments of the method and composition described herein, a layer of silicon-containing dielectric material is deposited on at a least a portion of a substrate via a chemical vapor deposition (CVD) process employing a reaction chamber. The method thus includes the step of includes the step of providing a substrate within a reaction chamber. Suitable substrates include, but are not limited to, semiconductor materials such as gallium arsenide (“GaAs”), silicon, and compositions containing silicon such as crystalline silicon, polysilicon, amorphous silicon, epitaxial silicon, silicon dioxide (“SiO₂”), silicon glass, silicon nitride, fused silica, glass, quartz, borosilicate glass, and combinations thereof. Other suitable materials include chromium, molybdenum, and other metals commonly employed in semi-conductor, integrated circuits, flat panel display, and flexible display applications. The substrate may have additional layers such as, for example, silicon, SiO₂, organosilicate glass (OSG), fluorinated silicate glass (FSG), boron carbonitride, silicon carbide, hydrogenated silicon carbide, silicon nitride, hydrogenated silicon nitride, silicon carbonitride, hydrogenated silicon carbonitride, boronitride, organic-inorganic composite materials, photoresists, organic polymers, porous organic and inorganic materials and composites, metal oxides such as aluminum oxide, and germanium oxide. Still further layers can also be germanosilicates, aluminosilicates, copper and aluminum, and diffusion barrier materials such as, but not limited to, TiN, Ti(C)N, TaN, Ta(C)N, Ta, W, or WN.

The reaction chamber is typically, for example, a thermal CVD or a plasma enhanced CVD reactor or a batch furnace type reactor in a variety of ways. In one embodiment, a liquid delivery system may be utilized. In liquid delivery formulations, the precursors described herein may be delivered in neat liquid form, or alternatively, may be employed in solvent formulations or compositions comprising same. Thus, in certain embodiments the precursor formulations may include solvent component(s) of suitable character as may be desirable and advantageous in a given end use application to form a film on a substrate.

The method disclosed herein includes the step of introducing into the reaction chamber a gaseous composition comprising monoalkoxysilane. In some embodiments, the composition may include additional reactants such as, for example, oxygen-containing species such as, for example, O₂, O₃, and N₂O, gaseous or liquid organic substances, CO₂, or CO. In one particular embodiment, the reaction mixture introduced into the reaction chamber comprises the at least one oxidant selected from the group consisting of O₂, N₂O, NO, NO₂, CO₂, water, H₂O₂, ozone, and combinations thereof. In an alternative embodiment, the reaction mixture does not comprise an oxidant.

The composition for depositing the dielectric film described herein comprises from about 40 to about 100 weight percent of monoalkoxysilane.

In embodiments, the gaseous composition comprising monoalkoxysilane can be used with hardening additives to further increase the elastic modulus of the as deposited films.

In embodiments, the gaseous composition comprising monoalkoxysilane is substantially free of or free of halides such as, for example, chlorides.

In addition to the monoalkoxysilane, additional materials can be introduced into the reaction chamber prior to, during and/or after the deposition reaction. Such materials include, e.g., inert gas (e.g., He, Ar, N₂, Kr, Xe, etc., which may be employed as a carrier gas for lesser volatile precursors and/or which can promote the curing of the as-deposited materials and provide a more stable final film).

Any reagent employed, including the monoalkoxysilane can be carried into the reactor separately from distinct sources or as a mixture. The reagents can be delivered to the reactor system by any number of means, preferably using a pressurizable stainless steel vessel fitted with the proper valves and fittings to allow the delivery of liquid to the process reactor. Preferably, the precursor is delivered into the process vacuum chamber as a gas, that is, the liquid must be vaporized before it is delivered into the process chamber.

The method disclosed herein includes the step of applying energy to the gaseous composition comprising monoalkoxysilane in the reaction chamber to induce reaction of the gaseous composition comprising monoalkoxysilane to deposit an organosilica film on the substrate, wherein the organosilica film has a dielectric constant of from about 2.8 to about 3.3 in some embodiments, 2.90 to 3.2 in other embodiments, and 3.0 to 3.2 in still preferred embodiments, an elastic modulus of from about 9 to about 32 GPa, preferably from 10 to 29 GPa, and an at. % carbon of from about 10 to about 30 as measured by XPS. Energy is applied to the gaseous reagents to induce the monoalkoxysilane and other reactants, if present, to react and to form the film on the substrate. Such energy can be provided by, e.g., plasma, pulsed plasma, helicon plasma, high density plasma, inductively coupled plasma, remote plasma, hot filament, and thermal (i.e., non-filament) and methods. A secondary rf frequency source can be used to modify the plasma characteristics at the substrate surface. Preferably, the film is formed by plasma enhanced chemical vapor deposition (“PECVD”).

The flow rate for each of the gaseous reagents preferably ranges from 10 to 5000 sccm, more preferably from 30 to 3000 sccm, per single 300 mm wafer. The actual flow rates needed may depend upon wafer size and chamber configuration, and are in no way limited to 300 mm wafers or single wafer chambers.

In certain embodiments, the film is deposited at a deposition rate of from about about 5 to about 700 nanometers (nm) per minute. In other embodiments, the film is deposited at a deposition rate of from about 30 to 200 nanometers (nm) per minute.

The pressure in the reaction chamber during deposition typically ranges from about 0.01 to about 600 torr or from about 1 to 15 torr.

The film is preferably deposited to a thickness of 0.001 to 500 microns, although the thickness can be varied as required. The blanket film deposited on a non-patterned surface has excellent uniformity, with a variation in thickness of less than 3% over 1 standard deviation across the substrate with a reasonable edge exclusion, wherein e.g., a 5 mm outermost edge of the substrate is not included in the statistical calculation of uniformity.

In addition to the inventive OSG products, the present invention includes the process by which the products are made, methods of using the products and compounds and compositions useful for preparing the products. For example, a process for making an integrated circuit on a semiconductor device is disclosed in U.S. Pat. No. 6,583,049, which is herein incorporated by reference.

The dense organosilica films produced by the disclosed methods exhibit excellent resistance to plasma induced damage, particularly during etch and photoresist strip processes.

The dense organosilica films produced by the disclosed methods exhibit excellent mechanical properties for a given dielectric constant relative to dense organosilica films having the same dielectric constant but made from a precursor that is not monoalkoxysilane. The resulting organosilica film (as deposited) typically has a dielectric constant of from about 2.8 to about 3.3 in some embodiments, about 2.9 to about 3.2 in other embodiments, and about 3.0 to about 3.2 in still other embodiments, an elastic modulus of from about 9 to about 32 GPa, and an at. % carbon of from about 10 to about 30 as measured by XPS. In other embodiments, the resulting organosilica film has a dielectric constant of from about 2.9 to about 3.2 in some embodiments, and about 3.0 to about 3.20 in other embodiments, an elastic modulus of from about 9 to about 32 GPa, In other embodiments, the resulting organosilica film has an elastic modulus of from about 10 to about 29 in some embodiments, and about 11 to about 29 in other embodiments, and an at. % carbon of from about 10 to about 30 as measured by XPS.

The resultant dense organosilica films may also be subjected to a post treating process once deposited. Thus, the term “post-treating” as used herein denotes treating the film with energy (e.g., thermal, plasma, photon, electron, microwave, etc.) or chemicals to further enhance materials properties.

The conditions under which post-treating are conducted can vary greatly. For example, post-treating can be conducted under high pressure or under a vacuum ambient.

UV annealing is a preferred method conducted under the following conditions.

The environment can be inert (e.g., nitrogen, CO₂, noble gases (He, Ar, Ne, Kr, Xe), etc.), oxidizing (e.g., oxygen, air, dilute oxygen environments, enriched oxygen environments, ozone, nitrous oxide, etc.) or reducing (dilute or concentrated hydrogen, hydrocarbons (saturated, unsaturated, linear or branched, aromatics), etc.). The pressure is preferably about 1 Torr to about 1000 Torr. However, a vacuum ambient is preferred for thermal annealing as well as any other post-treating means. The temperature is preferably 200-500° C., and the temperature ramp rate is from 0.1 to 100 deg ° C./min. The total UV annealing time is preferably from 0.01 min to 12 hours.

The invention will be illustrated in more detail with reference to the following Examples, but it should be understood that it is not deemed to be limited thereto. It is also recognized that the precursors described in this invention can also be used to deposit porous low k films with similar process advantages relative to existing porous low k films (that is a higher elastic modulus and greater resistance to plasma induced damage for a given value of the dielectric constant).

### EXAMPLES

### Example 1: Synthesis of di(ethyl)methyl-iso-propoxysilane

In a 500 ml flask, 100 mg Ru₃(CO)₁₂ was dissolved in 20 g THF. Then 200 g (3.33 mol) IPA (isopropyl alcohol) was added. This solution was heated to 75° C. With stirring, 200 g (1.96 mol) di(ethyl)methylsilane was added dropwise through an addition funnel. The reaction was exothermic and hydrogen bubbles were observed. After the addition was completed, the reaction mixture was stirred at the temperature for 30 min. Excess IPA and THF was removed by distillation at atmospheric pressure. A factional vacuum distillation produced 250 g di(ethyl)methyl-iso-propoxysilane (purity 99.3%), with boiling point of 63° C. at 50 mmHg. The yield was 80%. GC-MS: 160 (M+), 145, 131, 101, 88, 73, 61, 45.

### Example 2: Synthesis di(methyl)-iso-propyl-iso-propoxysilane

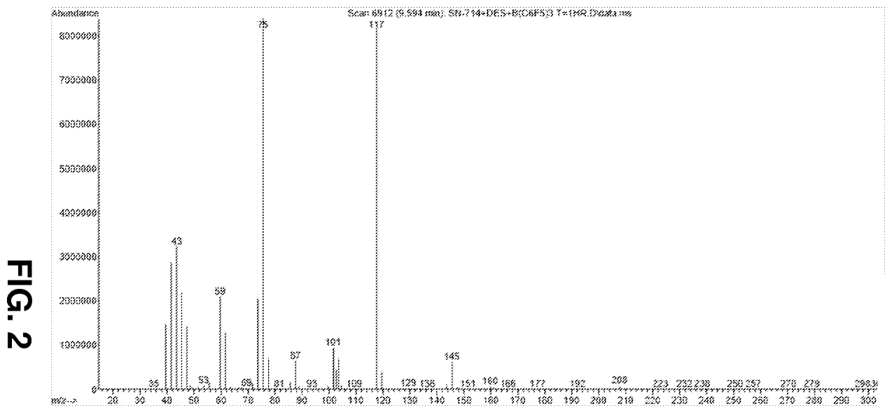

To 303.0 g (1.98 mol) di(methyl)-iso-propylchlorosilane in 1 L hexanes at room temperature was added 992 mL (1.98 mol) 2M isopropylmagnesium chloride in THF. The reaction mixture gradually increased in temperature to 60° C. Once addition was complete, it was allowed to cool to room temperature and stirred overnight. The resulting light gray slurry was filtered. Solvent was removed by distillation. Product was distilled at atmospheric pressure. A factional vacuum distillation produced 218 g di(methyl)iso-propyl-iso-propoxysilane with boiling point of 134° C. FIG. 2 is a chart depicting GC-MS data di(methyl)iso-propyl-iso-propoxysilane as synthesized. The yield was 69%. GC-MS: 160 (M+), 145, 117, 101, 87, 75, 49, 45.

All deposition experiments below were performed on a 300 mm AMAT Producer®SE, which deposits films on two wafers at the same time. Thus, the precursor and gas flow rates correspond to the flow rates required to deposit films on two wafers at the same time. The stated RF power per wafer is correct, as each wafer processing station has its own independent RF power supply. The stated deposition pressure is correct, as both wafer processing stations are maintained at the same pressure. The Producer® SE was fitted with a Producer® Nanocure chamber, that was used to UV cure certain films after the deposition process was complete.

Although illustrated and described above with reference to certain specific embodiments and examples, the present invention is nevertheless not intended to be limited to the details shown. Rather, various modifications may be made in the details within the scope and range of equivalents of the claims and without departing from the spirit of the invention. It is expressly intended, for example, that all ranges broadly recited in this document include within their scope all narrower ranges which fall within the broader ranges. It is also recognized that the compounds disclosed in Formula (1) and Formula (2) in this invention can be used as a structure former for the deposition of porous low k films with a high elastic modulus, a high XPS carbon content, and a high resistance to plasma induced damage.

Thickness and refractive index were measured on a Woollam model M2000 Spectroscopic Ellipsometer. Dielectric constants were determined using Hg probe technique on mid-resistivity p-type wafers (range 8-12 ohm-cm). FTIR spectra were measured using a Thermo Fisher Scientific Model iS50 spectrometer fitted with a nitrogen purged Pike Technologies Map300 for handling 12-inch wafers. FTIR spectra were used to calculate the relative density of bridging disilylmethylene groups in the film. The total density of terminal silicon methyl groups in the film (i.e., the Si-Me or Si(CH₃)ₓ density, wherein x is 1, 2, or 3), as determined by infrared spectroscopy, is defined as 1E2 times the area of the Si(CH₃)ₓ infrared band centered near 1270 cm⁻¹ divided by the area of the SiOₓ bands between approximately 1250 cm⁻¹ to 920 cm⁻¹. The relative density of bridging disilylmethylene groups in the film (i.e., the SiCH₂Si density), as determined by infrared spectroscopy, is defined as 1E4 times the area of the SiCH₂Si infrared band centered near 1360 cm⁻¹ divided by the area of the SiOₓ bands between approximately 1250 cm⁻¹ to 920 cm⁻¹. Mechanical properties were determined using a KLA iNano Nano Indenter.

Compositional data were obtained by x-ray photoelectron spectroscopy (XPS) on either a PHI 5600 (73560, 73808) or a Thermo K-Alpha (73846) and are provided in atomic weight percent. The atomic weight percent (%) values reported in the table do not include hydrogen.

For each precursor in the examples listed below the deposition conditions were optimized to yield films with high mechanical properties at a dielectric constant of 3.1 or 3.2.

### Comparative Example 3: Deposition of a Dense Diethoxymethylsilane (DEMS®) Based Film

A dense DEMS® based film was deposited using the following process conditions for 300 mm processing. The DEMS® precursor was delivered to the reaction chamber via direct liquid injection (DLI) at a flow rate of 750 mg/min using 1500 sccm He carrier gas flow, 380 milli-inch showerhead/heated pedestal spacing, 345° C. pedestal temperature, 10 Torr chamber pressure to which a 300 Watt 13.56 MHz plasma was applied. Various attributes of the film (e.g., dielectric constant (k), elastic modulus and hardness, densities of various functional groups as determined by infrared spectroscopy, and atomic composition by XPS (% C, % O, and % Si) were obtained as described above and are provided in Table 2.

### Comparative Example 4: Deposition of a Dense Diethoxymethylsilane (DEMS®) Based Film

A dense DEMS® based film was deposited using the following process conditions for 300 mm processing. The DEMS® precursor was delivered to the reaction chamber via direct liquid injection (DLI) at a flow rate of 750 mg/min using 2250 sccm He carrier gas flow, a 380 milli-inch showerhead/heated pedestal spacing, 345° C. pedestal temperature, 10 Torr chamber pressure to which a 200 Watt 13.56 MHz plasma was applied. Various attributes of the film (e.g., dielectric constant (k), elastic modulus and hardness, densities of various functional groups as determined by infrared spectroscopy, and atomic composition by XPS (% C, % O, and % Si) were obtained as described above and are provided in Table 3.

### Comparative Example 5: Deposition of a Dense 1-Methyl-1-isopropoxy-1-silacyclopentance (MPSCP) Based Film

A dense MPSCP based film was deposited using the following process conditions for 300 mm processing. The MPSCP precursor was delivered to the reaction chamber via direct liquid injection (DLI) at a flow rate of 850 mg/min using 750 sccm He carrier gas flow, 380 milli-inch showerhead/heated pedestal spacing, 390° C. pedestal temperature, 7.5 Torr chamber pressure to which a 225 Watt 13.56 MHz plasma was applied. Various attributes of the film (e.g., dielectric constant (k), elastic modulus and hardness, densities of various functional groups as determined by infrared spectroscopy, and atomic composition by XPS (% C, % O, and % Si) were obtained as described above and are provided in Table 2.

### Comparative Example 6: Deposition of a Dense 1-Methyl-1-isopropoxy-1-silacyclopentance (MPSCP) Based Film

A dense MPSCP based film was deposited using the following process conditions for 300 mm processing. The MPSCP precursor was delivered to the reaction chamber via direct liquid injection (DLI) at a flow rate of 850 mg/min using 750 sccm He carrier gas flow, 380 milli-inch showerhead/heated pedestal spacing, 390° C. pedestal temperature, 7.5 Torr chamber pressure to which a 275 Watt 13.56 MHz plasma was applied. Various attributes of the film (e.g., dielectric constant (k), elastic modulus and hardness, densities of various functional groups as determined by infrared spectroscopy, and atomic composition by XPS (% C, % O, and % Si) were obtained as described above and are provided in Table 3.

### Example 7: Deposition of a Dense Di(ethyl)methyl-isopropoxysilane (DEMIPS) Based Film

A dense Di(ethyl)methyl-isopropoxysilane based film was deposited using the following process conditions for 300 mm processing. The Di(ethyl)methyl-isopropoxysilane precursor was delivered to the reaction chamber via direct liquid injection (DLI) at a flow rate of 850 mg/min using 750 sccm He carrier gas flow, an O₂ flow rate of 8 sccm, 380 milli-inch showerhead/heated pedestal spacing, 390° C. pedestal temperature, 7.5 Torr chamber pressure to which a 225 Watt 13.56 MHz plasma was applied. Various attributes of the film (e.g., dielectric constant (k), elastic modulus and hardness, densities of various functional groups as determined by infrared spectroscopy, and atomic composition by XPS (% C, % O, and % Si) were obtained as described above and are provided in Table 2.

### Example 8: Deposition of a Dense Di(ethyl)methyl-isopropoxysilane Based Film

A dense di(ethyl)methyl-isopropoxysilane based film was deposited using the following process conditions for 300 mm processing. The di(ethyl)methyl-isopropoxysilane precursor was delivered to the reaction chamber via direct liquid injection (DLI) at a flow rate of 850 mg/min using 750 sccm He carrier gas flow, an O₂ flow rate of 8 sccm, 380 milli-inch showerhead/heated pedestal spacing, 390° C. pedestal temperature, 7.5 Torr chamber pressure to which a 275 Watt 13.56 MHz plasma was applied. Various attributes of the film (e.g., dielectric constant (k), elastic modulus and hardness, densities of various functional groups as determined by infrared spectroscopy, and atomic composition by XPS (% C, % O, and % Si) were obtained as described above and are provided in Table 3.

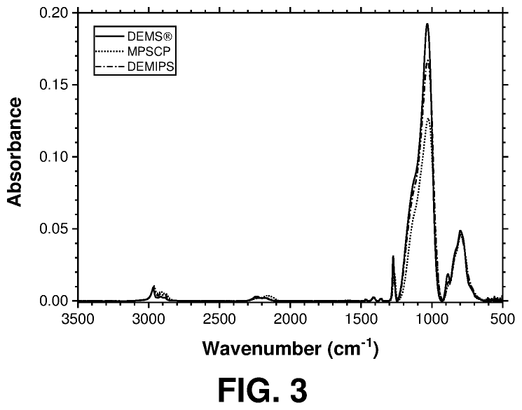

The processing conditions for depositions of dense low k films deposited using DEMIPS, DEMS®, and MPSCP as the low k precursor on a 300 mm PECVD reactor are given in Table 2 below. The processing conditions for each of these depositions were adjusted to obtain a high elastic modulus at a dielectric constant of 3.1. The infrared spectra of the dense low k films in Table 2 below are shown in FIG. 3. The relative densities of the Si(CH₃)ₓ groups and the SiCH₂Si groups in each film were calculated from its infrared spectrum as described earlier.

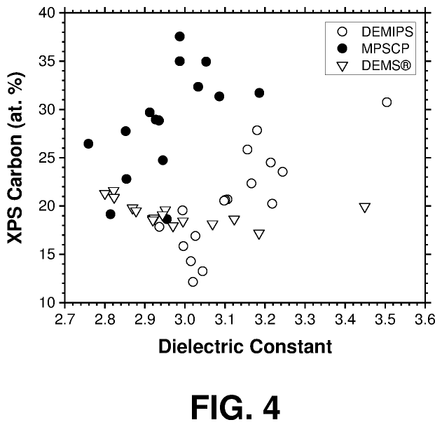

A series of depositions of dense low k dielectric films were deposited using either DEMIPS, DEMS®, or MPSCP as the low k precursor on a 300 mm PECVD reactor under a variety of process conditions from 170-425 Watts plasma power, 7.5-10 Torr chamber pressure, 345-390° C. substrate temperature, 0-30 sccm O₂ gas flow, 600-2250 sccm He carrier gas flow, 0.75 to 2.0 g/min of precursor liquid flow, and a 0.380 inch electrode spacing. The carbon content was measured by XPS as described herein. FIG. 4 shows the relationship between the carbon content (atomic %) of dense DEMIPS, DEMS®, and MPSCP® films having different dielectric constants. As FIG. 4 shows the prior art or DEMS® low k films had a narrow range of carbon content or from about 17 to 22 atomic % as the dielectric constant increased from about 2.75 to about 3.45. FIG. 4 also shows the prior art or MPSCP low k films had a wider range of carbon content or from about 19 to about 42 atomic % over the same dielectric constant range. The DEMIPS films also had a wide range of carbon content from about 12 to 31 atomic % over the same dielectric constant range, but in contrast the carbon content of the DEMIPS film was less than that of the MPSCP based film at the same dielectric constant. This illustrates one of the important advantages of using monoalkoxysilane compounds of Formula (1) or Formula (2) described herein as DEMIPS versus other prior art structure formers for depositing a dense low k dielectric film which is for similar values of the dielectric constant, the monoalkoxysilane precursor DEMIPS permits a wide tunable range of carbon content, but with less total carbon than prior art precursors such as MPSCP, but with more total carbon than prior art precursors such as DEMS©.

Table 2 provides a comparison of dense low k films with a dielectric constant of k=3.1 using DEMIPS, DEMS®, and MPSCP as the low k precursor. Processing conditions for a given film were adjusted to obtain a high elastic modulus without post processing treatments such as UV curing. Compared to the low carbon content prior art DEMS® and MPSCP based films the DEMIPS film has a significantly higher elastic modulus (about +20%). Further, the DEMIPS film has a higher carbon content (about +23%), a lower density of Si(CH₃) groups (about −30%), and higher density of SiCH₂Si groups (about +40%) than the DEMS® based film. Further, the DEMIPS film has a lower carbon content (about −40%), a lower density of Si(CH₃) groups (about −45%), and a lower density of SiCH₂Si groups (about −40%) than the MPSCP based films. This illustrates an important advantage of using monoalkoxysilane compounds of Formula (1) or Formula (2) described herein as DEMIPS versus other prior art structure formers for depositing a dense low k dielectric film which is for similar values of the dielectric constant, the monoalkoxysilane precursor DEMIPS permit the deposition of a low k dielectric film with a very high elastic modulus, a wide tunable range of carbon content, a low density of Si(CH₃) groups, and a high density of SiCH₂Si groups. For the same value of the dielectric constant DEMIPS based films have more total carbon content than prior art precursors such as DEMS® based films that result in films with low total carbon content and less total carbon content than prior art precursors such as MPSCP that result in films with high total carbon content. This is a very important distinction as the very high carbon content and high Si(CH₃) density of prior art MPSCP based films ultimately limits the highest elastic modulus that can obtained using this class of precursor. In contrast prior art precursors such as DEMS® that result in films with low carbon content incorporate carbon into the oxide network primarily as Si(CH₃) groups instead of as SiCH₂Si, thus limiting the highest elastic modulus that can be obtained with this class of precursor. Further, low carbon content prior art precursors such as DEMS® have a limited resistance to plasma induced damage (PID) due to their low carbon content. This illustrates another important advantage of using monoalkoxysilane compounds of Formula (1) or Formula (2) described herein as DEMIPS versus other prior art structure formers for depositing a dense low k dielectric film which is for similar values of the dielectric constant, the monoalkoxysi lane precursor DEMIPS permits the deposition of films with a high elastic modulus and a high resistance to plasma induced damage due to its intermediate carbon content, low density of Si(CH₃) groups, and high density of SiCH₂Si groups relative to prior art precursors such as DEMS®. Indeed, the combination of a high elastic modulus, intermediate carbon content, low Si(CH₃) density, and high SiCH₂Si density is expected to provide similar resistance to PID as prior art precursors such as MPSCP that result in the deposition of low k films with a higher carbon content than DEMIPS based films.

TABLE 2
Processing conditions for select films with a dielectric constant
of 3.1 that were adjusted to obtain a high elastic modulus.

| | | | 1-Methyl-1- |
|---|---|---|---|
| | Di(ethyl)methyl- | Diethoxy- | isopropoxy-1- |
| | isopropoxysilane | methylsilane | silacyclopentane |
| | (DEMIPS) | (DEMS ®) | (MPSCP) |
| Power (W) | 225 | 300 | 225 |
| Temperature (° C.) | 390 | 345 | 390 |
| Low k Precursor | 850 | 750 | 850 |
| Flow (mg/min) | | | |
| He Carrier Gas | 750 | 1500 | 750 |
| Flow (sccm) | | | |
| O₂ Flow (sccm) | 8 | 0 | 0 |
| Pressure (Torr) | 7.5 | 10 | 7.5 |
| Dielectric Constant | 3.1 | 3.1 | 3.1 |
| Elastic Modulus | 25 | 21 | 21 |
| (GPa) | | | |
| Hardness (GPa) | 3.6 | 3.0 | 3.2 |
| Si(CH3)x Density | 1.6 | 2.3 | 2.9 |
| SiCH2Si Density | 15 | 11 | 26 |
| % C | 23 | 19 | 38 |
| % O | 42 | 46 | 29 |
| % Si | 35 | 35 | 33 |

Table 3 provides a comparison of dense low k films with a dielectric constant of k=3.2 using DEMIPS, DEMS®, and MPSCP as the low k precursor. Processing conditions for a given film were adjusted to obtain a high elastic modulus without post processing treatments such as UV curing. Compared to the low carbon content prior art DEMS® and MPSCP based films the DEMIPS film has a significantly higher elastic modulus (about +16-20%). Further, the DEMIPS film has a higher carbon content (about +57%), a lower density of Si(CH₃) groups (about −20%), and higher density of SiCH₂Si groups (about +35%) than the DEMS® based film. Further, the DEMIPS film has a lower carbon content (about −33%), a lower density of Si(CH₃) groups (about −41%), and a lower density of SiCH₂Si groups (about −36%) than the MPSCP based films. This illustrates an important advantage of using monoalkoxysilane compounds of Formula (1) or Formula (2) described herein as DEMIPS versus other prior art structure formers for depositing a dense low k dielectric film which is for similar values of the dielectric constant, the monoalkoxysilane precursor DEMIPS permits the deposition of a low k dielectric film with a very high elastic modulus, a wide tunable range of carbon content, a low density of Si(CH₃) groups, and a high density of SiCH₂Si groups. For the same value of the dielectric constant DEMIPS based films have more total carbon content than prior art precursors such as DEMS® based films and less total carbon content than prior art precursors such as MPSCP. This is a very important distinction as the very high carbon content and high Si(CH₃) density of prior art MPSCP based films ultimately limits the highest elastic modulus that can obtained using this class of precursor. In contrast prior art precursors such as DEMS® that result in films with low carbon content incorporate carbon into the oxide network primarily as Si(CH₃) groups instead of as SiCH₂Si, thus limiting the highest elastic modulus that can be obtained with this class of precursor. Further, low carbon content prior art precursors such as DEMS® have a limited resistance to plasma induced damage (PID) due to their low carbon content. This illustrates another important advantage of using monoalkoxysilane compounds of Formula (1) or Formula (2) described herein as DEMIPS versus other prior art structure formers for depositing a dense low k dielectric film which is for similar values of the dielectric constant, the monoalkoxysilane precursor DEMIPS permits the deposition of films with a higher elastic modulus and an expected higher resistance to plasma induced damage than prior art precursors such as DEMS®. This is due to the higher carbon content, lower density of Si(CH₃) groups, and higher density of SiCH₂Si groups in DEMIPS based films relative to films deposited from prior art precursors such as DEMS®. Indeed, the combination of a high elastic modulus, intermediate carbon content, low Si(CH₃) density, and high SiCH₂Si density is expected to provide similar resistance to PID as prior art precursors such as MPSCP, even though such MPSCP based films result in the deposition of low k films with a higher carbon content than DEMIPS based films.

TABLE 3
Processing conditions for select films with a dielectric constant
of 3.2 that were adjusted to obtain a high elastic modulus.

| | Diethyl- | | 1-Methyl-1 - |
|---|---|---|---|
| | isopropoxy- | Diethoxy- | isopropoxy-1- |
| | methylsilane | methylsilane | silacyclopentane |
| | (DEMIPS) | (DEMS ®) | (MPSCP) |
| Power (W) | 275 | 200 | 275 |
| Temperature (° C.) | 390 | 345 | 390 |
| Low k Precursor Flow | 850 | 750 | 850 |
| (mg/min) | | | |
| He Carrier Gas Flow | 750 | 2250 | 750 |
| (sccm) | | | |
| O₂ Flow (sccm) | 8 | 0 | 0 |
| Pressure (Torr) | 7.5 | 10 | 7.5 |
| Dielectric Constant | 3.2 | 3.2 | 3.2 |
| Elastic Modulus (GPa) | 27 | 24 | 23 |
| Hardness (GPa) | 4.0 | 3.6 | 3.4 |
| Si(CH₃)ₓ Density | 1.7 | 2.1 | 2.9 |
| SiCH₂Si Density | 18 | 13 | 28 |
| % C | 27 | 17 | 39 |
| % O | 38 | 47 | 28 |
| % Si | 35 | 36 | 33 |

1. A method for making a dense organosilica film with improved mechanical properties, the method comprising:
providing a substrate within a reaction chamber; introducing into the reaction chamber a gaseous composition comprising a monoalkoxysilane having the structure given in Formulae (1) or (2):
R¹R²MeSiOR³ (1)
wherein R¹ and R² are selected independently from a linear or branched C₁ to C₅ alkyl, preferably ethyl, propyl, iso-propyl, butyl, sec-butyl, or tert-butyl and R³ is selected from a linear or branched C₁ to C₅ alkyl, preferably methyl, ethyl, propyl, iso-propyl, butyl, sec-butyl, iso-butyl, or tert-butyl.
R⁴(Me)₂SiOR⁵ (2)
wherein R⁴ is selected from a linear or branched C₁ to C₅ alkyl, preferably ethyl, propyl, iso-propyl, butyl, sec-butyl, or tert-butyl and R⁵ is selected from a linear or branched C₁ to C₅ alkyl, preferably ethyl, propyl, iso-propyl, n-butyl, sec-butyl, iso-butyl, or tert-butyl and wherein the monoalkoxysilane of Formulae (1) or (2) is substantially free of one or more impurities selected from the group consisting of a halide, water, metals, and combinations thereof; and
applying energy to the gaseous composition comprising monoalkoxysilane in the reaction chamber to induce reaction of the gaseous composition comprising monoalkoxysilane to deposit an organosilica film on the substrate, wherein the organosilica film has a dielectric constant of from about 2.8 to about 3.30 and an elastic modulus of from about 9 to about 32 GPa.

2. The method of claim 1 wherein the gaseous composition comprising monoalkoxysilane is free of a hardening additive.

3. The method of claim 1 which is a chemical vapor deposition method.

4. The method of claim 1 which is a plasma enhanced chemical vapor deposition method.

5. The method of claim 1 wherein the gaseous composition comprising monoalkoxysilane further comprises the at least one oxidant selected from the group consisting of O₂, N₂O, NO, NO₂, CO₂, CO, water, H₂O₂, ozone, and combinations thereof.

6. The method of claim 1 wherein the gaseous composition comprising monoalkoxysilane does not comprise an oxidant.

7. The method of claim 1 wherein the reaction chamber in the applying step comprises at least one gas selected from the group consisting of He, Ar, N₂, Kr, Xe, CO₂, and CO.

8. The method of claim 1 wherein the organosilica film has a refractive index (RI) of from about 1.3 to about 1.6 at 632 nm and carbon content as measured by XPS of from about 10 at. % to about 30 at. %.

9. The method of claim 1 wherein the organosilica film is deposited at a rate of from about 5 nm/min to about 700 nm/min.

10. The method of claim 8 wherein the organosilica film has a SiCH₂Si/SiOₓ*1E4 IR ratio of from about 8 to about 30.

11. A composition for a vapor deposition of a dielectric film comprising a monoalkoxysilane having the structure given in Formulae (1) or (2):
R¹R²MeSiOR³ (1)
where R¹ and R² are selected independently from a linear or branched C₁ to C₅ alkyl, preferably ethyl, propyl, iso-propyl, butyl, sec-butyl, or tert-butyl and R³ is selected from a linear or branched C₁ to C₅ alkyl, preferably methyl, ethyl, propyl, iso-propyl, butyl, sec-butyl, iso-butyl, or tert-butyl.
R⁴(Me)₂SiOR⁵ (2)
where R⁴ is selected from a linear or branched C₁ to C₅ alkyl, preferably ethyl, propyl, iso-propyl, butyl, sec-butyl, or tert-butyl and R⁵ is selected from a linear or branched C₁ to C₅ alkyl, preferably ethyl, propyl, iso-propyl, n-butyl, sec-butyl, iso-butyl, or tert-butyl and wherein the monoalkoxysilane is substantially free of one or more impurities selected from the group consisting of a halide, water, and metals.

12. The composition of claim 11 wherein the monoalkoxysilane comprises at least one selected from the group consisting of di(ethyl)-methyl-methoxysilane, di(ethyl)-methyl-ethoxysilane, di(ethyl)-methyl-n-propoxysilane, di(ethyl)-methyl-iso-propoxysilane, di(ethyl)methyl(n-butoxy)silane, di(ethyl)methyl(sec-butoxy)silane, di(ethyl)methyl(tert-butoxy)silane, trimethyl(iso-propoxy)silane, trimethyl(iso-butoxy)silane, trimethyl(sec-butoxy)silane, trimethyl(n-butoxy)silane, trimethyl(tert-butoxy)silane, di(propyl)methyl(methoxy)silane, di(propyl)methyl(ethoxy)silane, di(propyl)methyl(propoxy)silane, di(propyl)methyl(iso-propoxy)silane, di(n-propyl)methyl(butoxy)silane, di(n-propyl)methyl(sec-butoxy)silane, di(n-propyl)methyl(tert-butoxy)silane, di(n-propyl)methyl(iso-butoxy)silane, di(iso-propyl)methyl(methoxy)silane, di(iso-propyl)methyl(ethoxy)silane, di(iso-propyl)methyl(propoxy)silane, di(iso-propyl)methyl(iso-propoxy)silane, di(iso-propyl)methyl(n-butoxy)silane, di(iso-propyl)methyl(sec-butoxy)silane, di(iso-propyl)methyl(tert-butoxy)silane, di(iso-propyl)methyl(iso-butoxy)silane, di(methyl)ethyl(methoxy)silane, di(methyl)ethyl(ethoxy)silane, di(methyl)ethyl(n-propoxy)silane, di(methyl)ethyl(iso-propoxy)silane, di(methyl)ethyl(n-butoxy)silane, di(methyl)ethyl(sec-butoxy)silane, di(methyl)-ethyl-tert-butoxysilane, di(methyl)ethyl(iso-butoxy)silane, di(methyl)n-propyl(methoxy)silane, di(methyl)n-propyl(ethoxy)silane, di(methyl)n-propyl(n-propoxy)silane, di(methyl)n-propyl(iso-propoxy)silane, di(methyl)n-propyl(butoxy)silane, di(methyl)n-propyl(sec-butoxy)silane, di(methyl)n-propyl(tert-butoxy)silane, di(methyl)n-propyl(iso-butoxy)silane, di(methyl)iso-propyl(methoxy)silane, di(methyl)iso-propyl(ethoxy)silane, di(methyl)iso-propyl(n-propoxy)silane, di(methyl)iso-propyl(iso-propoxy)silane, di(methyl)iso-propyl(n-butoxy)silane, di(methyl)iso-propyl(sec-butoxy)silane, di(methyl)iso-propyl(tert-butoxy)silane, di(methyl)iso-propyl(iso-butoxy)silane, di(methyl)n-butyl(methoxy)silane, di(methyl)n-butyl(ethoxy)silane, di(methyl)n-butyl(propoxy)silane, di(methyl)n-butyl(iso-propoxy)silane, di(methyl)n-butyl(n-butoxy)silane, di(methyl)-n-butyl(sec-butoxy)silane, di(methyl)n-butyl(tert-butoxy)silane, di(methyl)-n-butyl(iso-butoxy)silane, di(methyl)sec-butyl(methoxy)silane, di(methyl)sec-butyl(ethoxy)silane, di(methyl)sec-butyl(n-propoxy)silane, di(methyl)sec-butyl(iso-propoxy)silane, di(methyl)sec-butyl(n-butoxy)silane, di(methyl)sec-butyl(sec-butoxy)silane, di(methyl)sec-butyl(tert-butoxy)silane, di(methyl)sec-butyl(iso-butoxy)silane, di(methyl)tert-butyl(methoxy)silane, di(methyl)tert-butyl(ethoxy)silane, di(methyl)tert-butyl(propoxy)silane, di(methyl)tert-butyl(iso-propoxy)silane, di(methyl)tert-butyl(n-butoxy)silane, di(methyl)tert-butyl(sec-butoxy)silane, di(methyl)tert-butyl(tert-butoxy)silane, di(methyl)tert-butyl(iso-butoxy)silane, and combinations thereof.

13. The composition of claim 11, wherein the halides comprise chloride ions.

14. The composition of claim 13, wherein the chloride ions, if present, are present at a concentration of 50 ppm or less as measured by IC.

15. The composition of claim 13, wherein the chloride ions, if present, are present at a concentration of 10 ppm or less as measured by IC.

16. The composition of claim 13, wherein the chloride ions, if present, are present at a concentration of 5 ppm or less as measured by IC.
